(19) United States
(12) Patent Application Publication
(10) Pub. No.: US 2011/0061706 A1
(43) Pub. Date: Mar. 17, 2011

(54) THIN FILM TYPE SOLAR CELL AND METHOD FOR MANUFACTURING THE SAME, AND THIN FILM TYPE SOLAR CELL MODULE AND POWER GENERATION SYSTEM USING THE SAME

(75) Inventors: Chang Kyun PARK, Gyeonggi-do (KR); Hyung Dong KANG, Gyeonggi-do (KR)

(73) Assignee: JUSUNG ENGINEERING CO., LTD., Gyeonggi-do (KR)

(21) Appl. No.: 12/618,756

(22) Filed: Nov. 15, 2009

(30) Foreign Application Priority Data
Sep. 16, 2009 (KR) 10-2009-0087329

(51) Int. Cl. H01L 31/042; H01L 31/00

(52) U.S. Cl. 136/244; 438/73; 257/E31.001

(57) ABSTRACT

A thin film type solar cell with a plurality of unit cells connected in series is disclosed, wherein uniform energy conversion efficiency is maintained in all of the unit cells by improving the energy conversion efficiency in the unit cell with the relatively-low energy conversion efficiency, to thereby realize the improved energy conversion efficiency, the thin film type solar cell comprising the plurality of unit cells, each unit cell including a front electrode, a semiconductor layer, and a rear electrode sequentially deposited on a substrate, wherein the thin film type solar cell includes a first unit cell set including at least one first unit cell with a first cell width, and a second unit cell set including at least one second unit cell with a second cell width which is different from the first cell width, wherein the first unit cell set occupies 80 to 95% of an entire area of the unit cells, and the second unit cell set occupies 5 to 20% of the entire area of the unit cells.

### CROSS REFERENCE TO RELATED APPLICATIONS

This application claims the benefit of the Korean Patent Application No. P2009-0087329, filed on Sep. 16, 2009, which is hereby incorporated by reference as if fully set forth herein.

### BACKGROUND OF THE INVENTION

1. Field of the Invention

The present invention relates to a thin film type solar cell, and more particularly, to a thin film type solar cell with a plurality of unit cells connected in series.

2. Discussion of the Related Art

A solar cell with a property of semiconductor converts a light energy into an electric energy.

A structure and principle of the solar cell according to the related art will be briefly explained as follows. The solar cell is formed in a PN-junction structure where a positive (P)-type semiconductor makes a junction with a negative (N)-type semiconductor. When solar ray is incident on the solar cell with the PN-junction structure, holes (+) and electrons (−) are generated in the semiconductor owing to the energy of the solar ray. By an electric field generated in a PN junction area, the holes (+) are drifted toward the P-type semiconductor and the electrons (−) are drifted toward the N-type semiconductor, whereby an electric power is produced with an occurrence of electric potential.

The solar cell can be largely classified into a wafer type solar cell and a thin film type solar cell.

The wafer type solar cell uses a wafer made of a semiconductor material such as silicon. In the meantime, the thin film type solar cell is manufactured by forming a semiconductor in type of a thin film on a glass substrate.

With respect to efficiency, the wafer type solar cell is better than the thin film type solar cell. However, in the case of the wafer type solar cell, it is difficult to realize a small thickness due to difficulty in performance of the manufacturing process. In addition, the wafer type solar cell uses a high-priced semiconductor substrate, whereby its manufacturing cost is increased.

Even though the thin film type solar cell is inferior in efficiency to the wafer type solar cell, the thin film type solar cell has advantages such as realization of thin profile and use of low-priced material. Accordingly, the thin film type solar cell is suitable for a mass production.

The thin film type solar cell is manufactured by sequential steps of forming a front electrode on a substrate, forming a semiconductor layer on the front electrode, and forming a rear electrode on the semiconductor layer. With the increase in size of the substrate, energy conversion efficiency is deteriorated due to the increase in electrode resistance. Thus, a thin film type solar cell including a plurality of unit cells divided and connected in series has been proposed.

Hereinafter, a related art thin film type solar cell will be described with reference to the accompanying drawings.

FIG. 1(A) is a plan view illustrating a related art thin film type solar cell, and FIG. 1(B) is a cross section view along I-I of FIG. 1(A).

As shown in FIG. 1(A), a plurality of unit cells, that is, the first unit cell to the (n)th unit cell are formed on a substrate 10. The plurality of unit cells are connected in series, and are provided at fixed intervals by each separating channel 50 interposed in-between.

In more detail, as shown in FIG. 1(B), a plurality of front electrodes 20 are formed on the substrate 10, wherein the plurality of front electrodes 20 are provided at fixed intervals. Then, a plurality of semiconductor layers 30 are formed on the front electrodes 20. Also, a plurality of rear electrodes 40 are formed on the semiconductor layers 30, wherein the plurality of rear electrodes 40 are provided at fixed intervals by each separating channel 50 interposed in-between. Through each contact portion 35 formed in each semiconductor layer 30, the rear electrode 40 is electrically connected with the front electrode 20.

The front electrode 20, the semiconductor layer 30, and the rear electrode 40 sequentially deposited constitute each unit cell. According as the rear electrode 40 included in each corresponding unit cell is electrically connected with the front electrode 20 included in the neighboring unit cell, the plurality of unit cells are electrically connected in series.

The aforementioned related art thin film type solar cell discloses that the first to (n)th unit cells are formed in the same pattern. For example, the first to (n)th unit cells are designed in such a way that each of the first to (n)th unit cells has the same cell width (W).

In case of the related art thin film type solar cell with the plurality of unit cells electrically connected in series, even though the substrate 10 is increased in size, an electrode resistance is not increased so that it enables to prevent the energy conversion efficiency from being deteriorated. However, it is difficult to maintain uniformity in the energy conversion efficiency among the first to (n)th unit cells.

FIG. 2 is a graph illustrating the energy conversion efficiency of the first to (n)th unit cells in the related art thin film type solar cell. As shown in FIG. 2, the energy conversion efficiency in the unit cell positioned adjacent to the side of the thin film type solar cell is relatively lower than the energy conversion efficiency in the unit cell positioned adjacent to the center of the thin film type solar cell, whereby the total energy conversion efficiency of the thin film type solar cell is totally deteriorated.

In case of the related art thin film type solar cell with the plurality of unit cells connected in series, the energy conversion efficiency is not uniform in all of the unit cells, that is, the energy conversion efficiency in some of the unit cells is relatively lower that that of the other unit cells, whereby the total energy conversion efficiency is deteriorated.

### SUMMARY OF THE INVENTION

Accordingly, the present invention is directed to a thin film type solar cell that substantially obviates one or more problems due to limitations and disadvantages of the related art.

An object of the present invention is to provide a thin film type solar cell with a plurality of unit cells connected in series, wherein uniform energy conversion efficiency is maintained in all of the unit cells by improving the energy conversion efficiency in the unit cell with the relatively-low energy conversion efficiency, to thereby realize the improved energy conversion efficiency.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided a thin film type solar cell comprising a plurality of unit cells, each unit cell including a front electrode, a semiconductor layer, and a rear electrode sequentially deposited on a substrate, wherein the thin film type solar cell includes a first unit cell set including at least one first unit cell with a first cell width, and a second unit cell set including at least one second unit cell with a second cell width which is different from the first cell width, wherein the first unit cell set occupies 80 to 95% of an entire area of the unit cells, and the second unit cell set occupies 5 to 20% of the entire area of the unit cells.

In another aspect of the present invention, there is provided a thin film type solar cell comprising first and second solar cells on a substrate, wherein the first and second solar cells are formed at a predetermined interval therebetween so as to be separately driven when cutting the substrate into the first and second solar cells, wherein each of the first and second solar cells includes a plurality of unit cells, each unit cell including a front electrode, a semiconductor layer, and a rear electrode deposited in sequence, and wherein the plurality of unit cells constitute a first unit cell set provided with first unit cells and a second unit cell set provided with second unit cells, wherein each of the first unit cells has a first cell width, each of the second unit cells has a second cell width, and the first cell width is different from the second cell width, and wherein the first unit cell set occupies 80 to 95% of an entire area of the unit cells, and the second unit cell set occupies 5 to 20% of the entire area of the unit cells.

In another aspect of the present invention, there is provided a thin film type solar cell module comprising a thin film type solar cell including a plurality of unit cells, each unit cell including a front electrode, a semiconductor layer, and a rear electrode sequentially deposited on a substrate, wherein the plurality of unit cells constitute a first unit cell set including at least one first unit cell with a first cell width, and a second unit cell set including at least one second unit cell with a second cell width which is different from the first cell width, and wherein the first unit cell set occupies 80 to 95% of an entire area of the unit cells, and the second unit cell set occupies 5 to 20% of the entire area of the unit cells; a first connection wire for connecting the front electrode of the unit cell formed at one side of the substrate with the external, and a second connection wire for connecting the rear electrode of the unit cell formed at the other side of the substrate with the external; and a support frame for supporting the thin film type solar cell.

In another aspect of the present invention, there is provided a power generation system comprising a thin film type solar cell module and a power inverting device for inverting an output of the thin film type solar cell module, wherein the thin film type solar cell module comprises a thin film type solar cell including a plurality of unit cells, each unit cell including a front electrode, a semiconductor layer, and a rear electrode sequentially deposited on a substrate, wherein the plurality of unit cells constitute a first unit cell set including at least one first unit cell with a first cell width, and a second unit cell set including at least one second unit cell with a second cell width which is different from the first cell width, and wherein the first unit cell set occupies 80 to 95% of an entire area of the unit cells, and the second unit cell set occupies 5 to 20% of the entire area of the unit cells; a first connection wire for connecting the front electrode of the unit cell formed at one side of the substrate with the external, and a second connection wire for connecting the rear electrode of the unit cell formed at the other side of the substrate with the external; and a support frame for supporting the thin film type solar cell.

In another aspect of the present invention, there is provided a method for manufacturing a thin film type solar cell including a plurality of unit cells, each unit cell including a front electrode, a semiconductor layer, and a rear electrode sequentially deposited on a substrate, comprising forming a first unit cell set including at least one first unit cell with a first cell width; and forming a second unit cell set including at least one second unit cell with a second cell width, wherein the second cell width is different from the first cell width, wherein the first and second unit cell sets are formed by a laser scribing process using at least one laser for forming a separating channel.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1(A) is a plan view illustrating a related art thin film type solar cell, and FIG. 1(B) is a cross section view along I-I of FIG. 1(A);

FIG. 2 is a graph illustrating energy conversion efficiency in the first to (n)th unit cells included in a related art thin film type solar cell;

FIG. 3 is a plan view illustrating a thin film type solar cell according to one embodiment of the present invention;

FIG. 4 is a cross section view illustrating a thin film type solar cell according to one embodiment of the present invention;

FIG. 5 is a cross section view illustrating a thin film type solar cell module according to one embodiment of the present invention;

FIG. 6 is a cross section view illustrating a thin film type solar cell according to another embodiment of the present invention;

FIGS. 7 and 8 are plan views illustrating a thin film type solar cell according to another embodiment of the present invention;

FIGS. 9(A and B) are plan views illustrating a method for manufacturing a thin film type solar cell according to one embodiment of the present invention;

FIGS. 10(A to C) are plan views illustrating a method for manufacturing a thin film type solar cell according to another embodiment of the present invention; and

FIGS. 11(A and B) are plan views illustrating a method for manufacturing a thin film type solar cell according to another embodiment of the present invention.

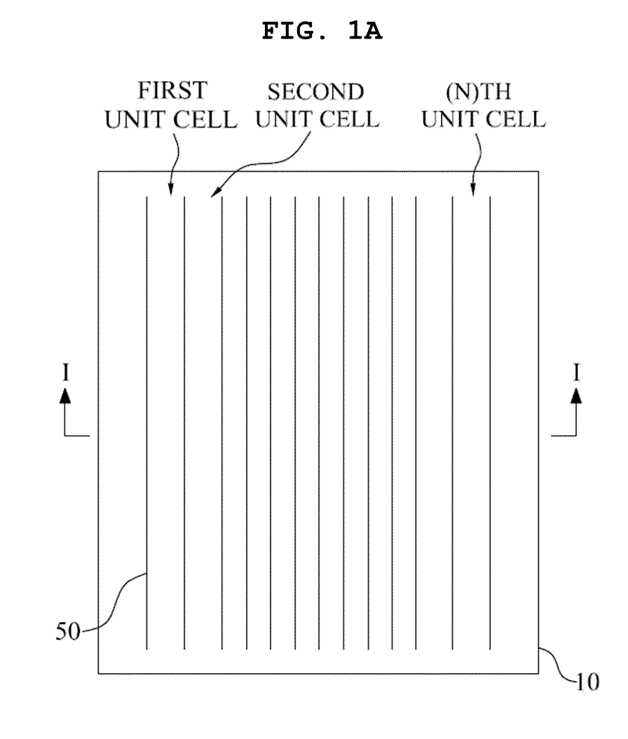

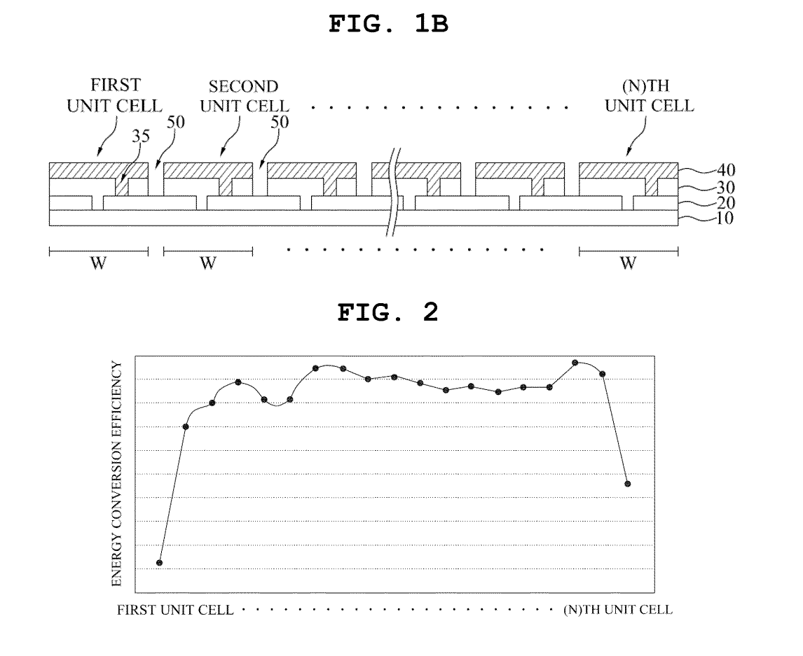

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, a thin film type solar cell according to the present invention will be described with reference to the accompanying drawings.

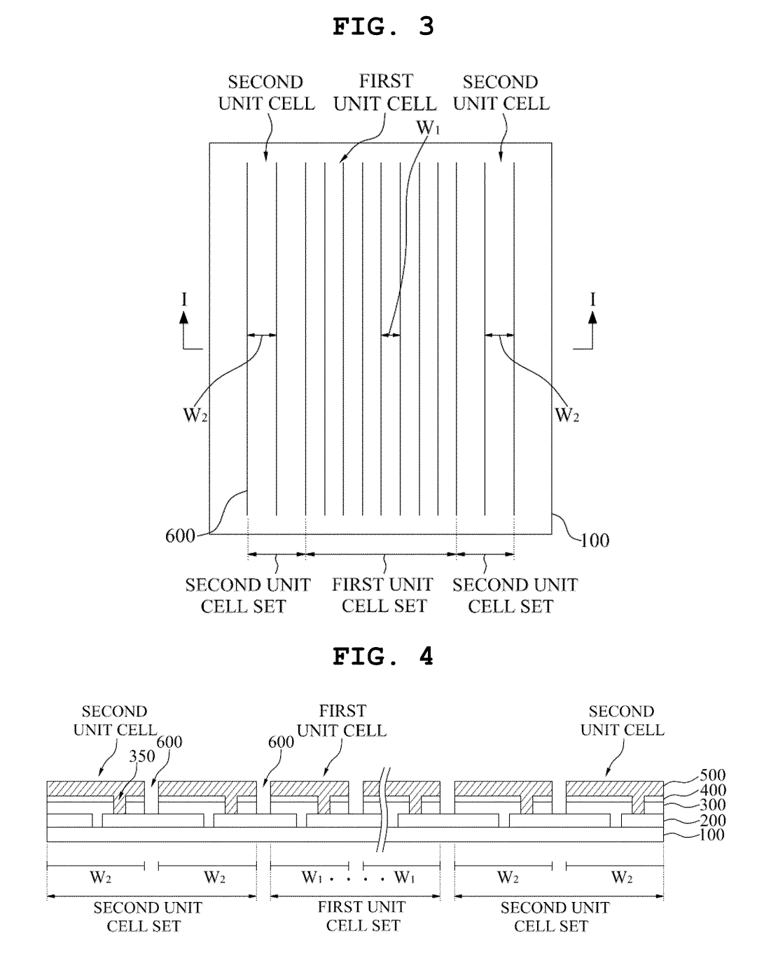

FIG. 3 is a plan view illustrating a thin film type solar cell according to one embodiment of the present invention.

As shown in FIG. 3, the thin film type solar cell according to one embodiment of the present invention includes a plurality of unit cells on a substrate 100. In more detail, the plurality of unit cells are connected in series, and are provided at fixed intervals by each separating channel 600 interposed in-between.

The plurality of unit cells constitute first and second unit cell sets, wherein the first unit cell set comprises first unit cells and the second unit cell set comprises second unit cells. Each of the first unit cells has a first cell width (W₁), and each of the second unit cells has a second cell width (W₂). The first unit cell set is formed in a central part of the substrate 100, and the second unit cell set is formed in each side of the substrate 100.

The second cell width (W₂) of the second unit cell is larger than the first cell width (W₁) of the first unit cell. According as the second cell width (W₂) of each of the second unit cells formed in the both sides of the substrate 100 is larger than the first cell width (W₁) of each of the first unit cells formed in the central part of the substrate 100, a short-circuit current is increased in the both sides of the substrate 100, thereby resulting in the improved energy conversion efficiency.

The plurality of unit cells included in the first unit cell set occupy about 80 to 95% of an entire area of the unit cells, and the plurality of unit cells included in the second unit cell set occupy about 5 to 20% of the entire area of the unit cells. If the area of the first unit cell set is less than 80%, an electrode resistance may be increased, and simultaneously it may be difficult to uniformly maintain the energy conversion efficiency in all of the unit cells. In the meantime, if the area of the first unit cell set is more than 95%, the area of the second unit cells with the increased short-circuit current is substantially decreased so that it is difficult to improve the energy conversion efficiency.

The second cell width (W₂) of each of the second unit cells may be 5 to 20% larger than the first cell width (W₁) of each of the first unit cells. If a difference between the second cell width (W₂) and the first cell width (W₁) is below 5%, it may be difficult to improve the energy conversion efficiency through the increase of short-circuit current. In the meantime, if the difference between the second cell width (W₂) and the first cell width (W₁) is above 20%, the electrode resistance may be increased so that the energy conversion efficiency of solar cell may be deteriorated.

The second cell width (W₂) may be set to be identical in all of the second unit cells, but it is not limited to this. The second cell width (W₂) may be set to be variable in the second unit cells. For example, the second cell width (W₂) of each second unit cell may be gradually increased as going toward each end of the substrate 100. That is, as shown in FIG. 2, since the energy conversion efficiency is gradually decreased as going toward each end of the substrate 100, the second cell width (W₂) of each second unit cell is gradually increased as going toward each end of the substrate 100, to thereby overcome the problem caused by the decreased energy conversion efficiency.

Hereinafter, a detailed structure of the thin film type solar cell of FIG. 3 according to one embodiment of the present invention will be described as follows. However, a detailed explanation for the same parts as the aforementioned those will be omitted.

FIG. 4 is a cross section view along I-I of FIG. 3 which illustrates the thin film type solar cell according to one embodiment of the present invention.

As shown in FIG. 4, the thin film type solar cell according to one embodiment of the present invention includes the substrate 100, a plurality of front electrodes 200, a plurality of semiconductor layers 300, a plurality of transparent conductive layers 400, and a plurality of rear electrodes 500.

The substrate 100 may be made of glass or transparent plastic.

The plurality of front electrodes 200 may be formed at fixed intervals on the substrate 100, wherein the front electrode 200 may be made of a transparent conductive material, for example, ZnO, ZnO:B, ZnO:Al, SnO₂, SnO₂:F, or ITO (Indium Tin Oxide).

The plurality of front electrodes 200 may be formed at fixed intervals by sequential steps of depositing the transparent conductive material on an entire surface of the substrate 100 by sputtering or MOCVD (Metal Organic Chemical Vapor Deposition), and selectively removing predetermined portions from the deposited transparent conductive material by a laser scribing process.

The front electrode 200 corresponds to a solar-ray incidence face. In this respect, it is important for the front electrode 200 to transmit the solar ray into the inside of the solar cell with the maximized absorption of solar ray. For this, the front electrode 200 may have an uneven surface which is made by a texturing process. The surface of material layer is provided with the uneven surface, that is, texture structure, through the texturing process, for example, an etching process using photolithography, an anisotropic etching process using a chemical solution, or a groove-forming process using a mechanical scribing. The front electrode 200 of the uneven structure enables to decrease a solar-ray reflection ratio on the solar cell, and to increase a solar-ray absorption ratio into the solar cell by a dispersion of the solar ray, thereby resulting in the improved cell efficiency.

The plurality of semiconductor layers 300 are formed on the front electrodes 200, wherein the plurality of semiconductor layers 300 are positioned at fixed intervals by each contact portion 350 or each separating channel 600 interposed in-between. The plurality of semiconductor layers 300 may be formed at fixed intervals by sequential steps of depositing a silicon-based semiconductor material such as amorphous silicon by plasma CVD, and selectively removing predetermined portions from the deposited silicon-based semiconductor material by a laser scribing process.

The semiconductor layer 300 may be formed in a PIN structure where a P-type semiconductor layer, an I-type semiconductor layer, and an N-type semiconductor layer are deposited in sequence. In the semiconductor layer 300 with the PIN structure, depletion is generated in the I-type semiconductor layer by the P-type semiconductor layer and the N-type semiconductor layer, whereby an electric field occurs therein. Thus, electrons and holes generated by the solar ray are drifted by the electric field, and the drifted electrons and holes are collected in the N-type semiconductor layer and the P-type semiconductor layer, respectively. If forming the semiconductor layer 300 with the PIN structure, the P-type semiconductor layer is firstly formed on the front electrode 200, and then the I-type and N-type semiconductor layers are formed thereon, preferably. This is because a drift mobility of the hole is less than a drift mobility of the electron. In order to maximize the efficiency in collection of the incident light, the P-type semiconductor layer is provided adjacent to the light-incidence face.

The plurality of transparent conductive layers 400 are formed on the semiconductor layers 300, wherein the transparent conductive layers 400 are provided at the same pattern type as the semiconductor layers 300. That is, the plurality of transparent conductive layers 400 are formed at fixed intervals by each contact portion 350 or each separating channel 600 interposed in-between.

The transparent conductive layer 400 may be formed at fixed intervals by sequential steps of depositing a transparent conductive material, for example, ZnO, ZnO:B, ZnO:Al, ZnO:H, or Ag by sputtering or MOCVD (Metal Organic Chemical Vapor Deposition), and selectively removing predetermined portions from the deposited transparent conductive material by a laser scribing process.

The transparent conductive layer 400 may be omitted. However, in order to improve the cell efficiency, forming the transparent conductive layer 400 is preferable to omitting the transparent conductive layer 400. This is because the transparent conductive layer 400 enables the solar ray transmitted through the semiconductor layer 300 to be dispersed in all angles, whereby the solar ray is reflected on the rear electrode layer 500 and is then re-incident on the semiconductor layer 300, thereby resulting in the improved cell efficiency.

The contact portions 350 formed in the semiconductor layer 300 and the transparent conductive layer 400 may be formed by sequential steps of depositing the silicon-based semiconductor material for the semiconductor layer 300, depositing the transparent conductive material for the transparent conductive layer 400, and performing the laser scribing process once.

The separating channels 600 formed in the semiconductor layer 300 and the transparent conductive layer 400 may be formed by sequential steps of depositing the silicon-based semiconductor material for the semiconductor layer 300, depositing the transparent conductive material for the transparent conductive layer 400, depositing a conductive material for the rear electrode 500, and performing the laser scribing process once.

The plurality of rear electrodes 500 are positioned at fixed intervals by each separating channel 600 interposed in-between. Each corresponding rear electrode 500 is electrically connected with the neighboring front electrode 200 through the contact portion 350, whereby the plurality of unit cells are connected in series.

A width of each rear electrode 500 corresponds to a cell width of each unit cell. Herein, the cell width indicates the width of each rear electrode 500 in each unit cell.

The width of each rear electrode 500 is determined based on the interval between each of the separating channels 600, and the cell width of each unit cell is determined based on the width of each rear electrode 500. Thus, the interval between each of the separating channels 600 should be adjusted in consideration to the cell width of each unit cell.

The plurality of rear electrodes 500 may be formed at fixed intervals by sequential steps of depositing a metal material, for example, Ag, Al, Ag+Al, Ag+Mg, Ag+Mn, Ag+Sb, Ag+Zn, Ag+Mo, Ag+Ni, Ag+Cu, or Ag+Al+Zn by sputtering, and selectively removing predetermined portions from the deposited metal material by a laser scribing process.

The plurality of rear electrodes 500 may be simultaneously formed at fixed intervals by one printing process without applying the additional laser scribing process. That is, the plurality of rear electrodes 500 may be patterned through the use of metal paste by a screen printing process, an inkjet printing process, a gravure printing process, or a microcontact printing process. In this case, after removing the predetermined portions from the silicon-based semiconductor material for the semiconductor layer 300 and the transparent conductive material for the transparent conductive layer 400, the plurality of rear electrodes 500 are patterned by the aforementioned printing process, thereby completing the separating channels 600.

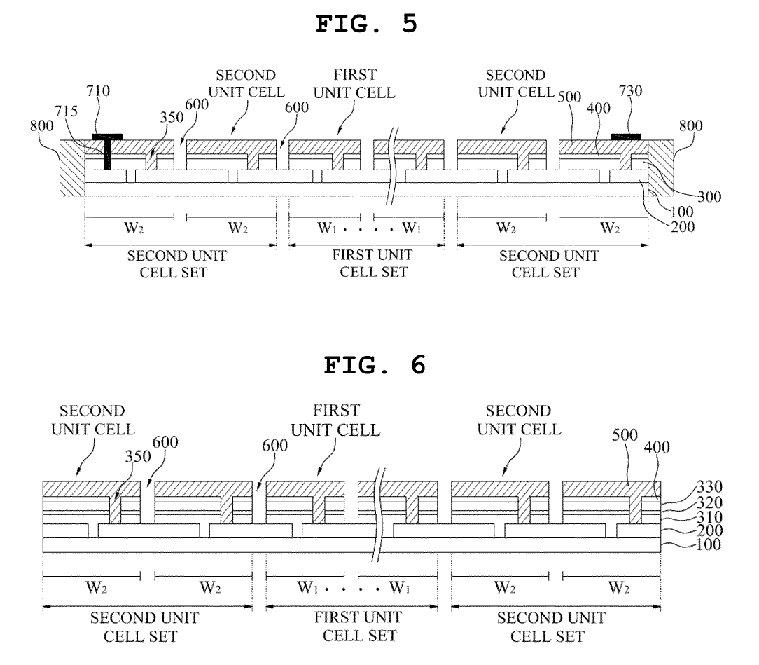

Hereinafter, a thin film type solar cell module including the aforementioned thin film type solar cell of FIG. 4 according to one embodiment of the present invention will be explained with reference to the accompanying drawings. FIG. 5 is a cross section view illustrating a thin film type solar cell module according to one embodiment of the present invention. Since the thin film type solar cell is identical to that of FIG. 4, the same reference numbers will be used throughout the drawings to refer to the same or like parts, and the detailed explanation for the same parts will be omitted.

As shown in FIG. 5, the thin film type solar cell module according to one embodiment of the present invention includes the aforementioned thin film type solar cell shown in FIG. 4; connection wires 710 and 730 for connecting the electrode of the thin film type solar cell with the external; and a support frame 800 for supporting the thin film type solar cell.

The connection wires 710 and 730 include first and second connection wires 710 and 730, wherein the first connection wire 710 connects the front electrode 200 of the unit cell positioned at one side of the substrate 100 with the external, and the second connection wire 730 connects the rear electrode 500 of the unit cell positioned at the other side of the substrate 100 with the external. The first connection wire 710 may be connected with the front electrode 200 through a contact hole 715.

There is a power generation system including the aforementioned thin film type solar cell module of FIG. 5 according to one embodiment of the present invention. The power generation system according to one embodiment of the present invention includes the aforementioned thin film type solar cell module shown in FIG. 5, and a power inverting device such as an inverter for inverting an output of the thin film type solar cell module.

As mentioned above, the thin film type solar cell according to one embodiment of the present invention can be applied to the thin film type solar cell module and power generation system according to one embodiment of the present invention. In the same manner, it is apparent that a thin film type solar cell according to another embodiment of the present invention can be applied to a thin film type solar cell module and power generation system according to another embodiment of the present invention.

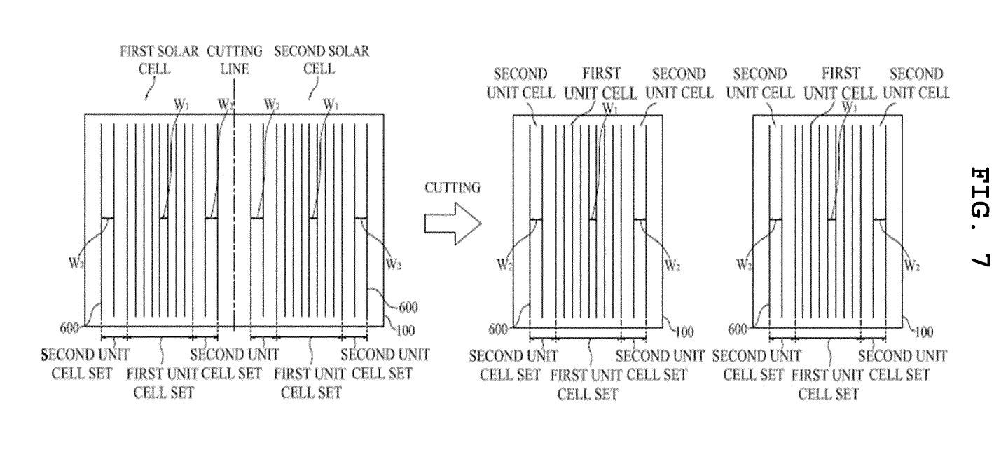

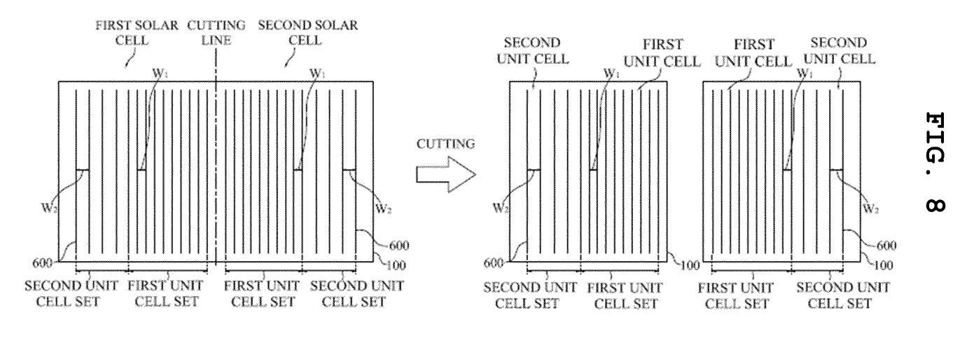

Hereinafter, a thin film type solar cell according to another embodiment of the present invention will be described as follows, which is also capable of being applied to a thin film type solar cell module and power generation system, as mentioned above. FIG. 6 is a cross section view along I-I of FIG. 4, wherein FIG. 6 illustrates a thin film type solar cell according to another embodiment of the present invention. Except a structure of semiconductor layer, the thin film type solar cell of FIG. 6 is identical to the thin film type solar cell of FIG. 5. Thus, wherever possible, the same reference numbers will be used throughout the drawings to refer to the same or like parts, and the detailed explanation for the same parts will be omitted.

As shown in FIG. 6, the thin film type solar cell according to another embodiment of the present invention includes a semiconductor layer positioned between a front electrode 200 and a transparent conductive layer 400. The semiconductor layer comprises first and second semiconductor layers 310 and 330 with a buffer layer 320 interposed therebetween. That is, the semiconductor layer is formed in a tandem structure where the first semiconductor layer 310, the buffer layer 320 and the second semiconductor layer 330 are deposited sequentially.

Each of the first and second semiconductor layers 310 and 330 may be formed in a PIN structure where a P-type semiconductor layer, an I-type semiconductor layer, and an N-type semiconductor layer are deposited in sequence.

The first semiconductor layer 310 may be formed of an amorphous semiconductor material of the PIN structure, and the second semiconductor layer 330 may be formed of a microcrystal line semiconductor material of the PIN structure.

The amorphous semiconductor material is characterized by absorption of short-wavelength light, and the microcrystalline semiconductor material is characterized by absorption of long-wavelength light. A mixture of the amorphous semiconductor material and the microcrystalline semiconductor material can enhance light-absorbing efficiency, but it is not limited to this type of mixture. That is, the first semiconductor layer 310 may be formed of amorphous semiconductor/germanium material, or microcrystalline semiconductor material; and the second semiconductor layer 330 may be formed of amorphous semiconductor material, or amorphous semiconductor/germanium material.

The buffer layer 320 is interposed between the first and second semiconductor layers 310 and 330, wherein the buffer layer 320 enables smooth drift of electron and hole by a tunnel junction. The buffer layer 320 may be made of a transparent material, for example, ZnO.

Instead of the tandem structure shown in FIG. 6, the semiconductor layer 300 may be formed in a triple structure. In case of the triple structure, each buffer layer is interposed between each of first, second and third semiconductor layers included in the semiconductor layer 300.

FIGS. 7 and 8 are plan views illustrating the thin film type solar cells according to other embodiments of the present invention. According as a substrate is increased in size, a plurality of solar cell patterns may be formed on the substrate, and then a cutting process is carried out to obtain a plurality of solar cells which are driven separately. This will be described as follows.

As shown in FIG. 7, the thin film type solar cell according to another embodiment of the present invention includes first and second solar cells respectively positioned at left and right portions of a substrate 100 with respect to a central line of the substrate 100, wherein the central line corresponds to a cutting line of the substrate 100.

When patterning the first and second solar cells on the substrate 100, a predetermined interval is provided therebetween so as to separately drive the first and second solar cells after completing the cutting process. Each of the first and second solar cells obtained after the cutting process is identical to the aforementioned thin film type solar cell shown in FIG. 3.

Each of the first and second solar cells includes a plurality of unit cells, wherein each unit cell comprises a front electrode, a semiconductor layer, and a rear electrode. The plurality of unit cells constitute first and second unit cell sets, wherein the first unit cell set comprises first unit cells and the second unit cell set comprises second unit cells. At this time, each of the first unit cells has a first cell width (W₁), and each of the second unit cells has a second cell width (W₂), wherein the second cell width (W₂) is larger than the first cell width (W₁).

Before cutting the substrate 100 into the first and second solar cells, the first and second unit cell sets are arranged in such a way that the second unit cell set is positioned at a central part of the substrate 100; the first unit cell sets are symmetrically positioned with respect to the centrally-positioned second unit cell set; and the second unit cell set is positioned next to each first unit cell set, that is, the second unit cell set is positioned at each side of the substrate 100.

After cutting the substrate 100 into the first and second solar cells, the first and second unit cell sets are arranged in such a way that the first unit cell set is positioned at a central part of each substrate 100 included in each of the first and second solar cells; and the second unit cell set is positioned at each side of each substrate 100 included in each of the first and second solar cells.

Both before and after cutting the substrate 100 into the first and second solar cells, the first and second unit cell sets are designed in such a way that the first unit cell sets occupy about 80 to 95% of an entire area of the unit cells, and the second unit cell sets occupy about 5 to 20% of the entire area of the unit cells.

The second cell width (W₂) of each of the second unit cells may be about 5 to 20% larger than the first cell width (W₁) of each of the first unit cells. Selectively, the respective second unit cells may be either fixed or varied in the second cell width (W₂). For example, the second width (W₂) of each second unit cell may be a fixed value in the respective second unit cells, or the second width (W₂) of each second unit cell may be gradually increased as going in a predetermined direction.

A thin film type solar cell of FIG. 8 is similar to the thin film type solar cell of FIG. 7 in that there are first and second solar cells respectively positioned at left and right portions of a substrate 100 with respect to a central line of the substrate 100, that is, a cutting line of the substrate 100. However, after cutting the substrate 100 into the first and second solar cells, each of the first and second solar cells is different to that of FIG. 7.

Before cutting the substrate 100 into the first and second solar cells, first and second unit cell sets are arranged in such a way the first unit cell set is positioned at a central part of the substrate 100, and the second unit cell set is positioned at each side of the substrate 100. That is, the same unit cell sets, for example, the first unit cell sets are provided at the neighboring sides of the first and second solar cells.

After cutting the substrate 100 into the first and second solar cells, the first and second unit cell sets are arranged in such a way that the first unit cell set is positioned at one side of the substrate 100 in each of the first and second solar cells, and the second unit cell set is positioned at the other side of the substrate 100 in each of the first and second solar cells.

Both before and after cutting the substrate 100 into the first and second solar cells, the first and second unit cell sets are designed in such a way that the first unit cell sets occupy about 80 to 95% of an entire area of the unit cells, and the second unit cell sets occupy about 5 to 20% of the entire area of the unit cells.

The second cell width (W₂) of each of the second unit cells may be about 5 to 20% larger than the first cell width (W₁) of each of the first unit cells. Selectively, the respective second unit cells may be either fixed or varied in the second cell width (W₂). For example, the second width (W₂) may be a fixed value in the respective second unit cells, or the second width (W₂) of each second unit cell may be gradually increased as going in a predetermined direction.

Hereinafter, a method for manufacturing a thin film type solar cell according to the present invention will be described with reference to the accompanying drawings.

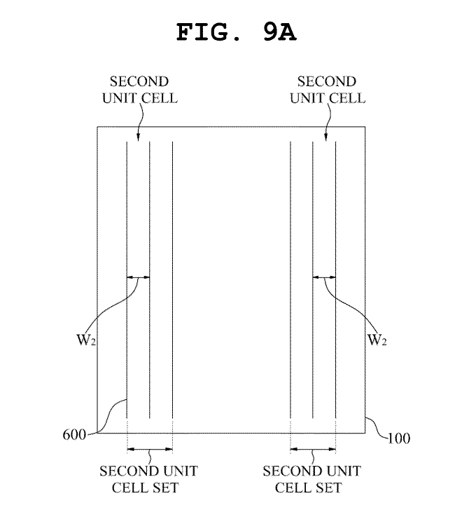

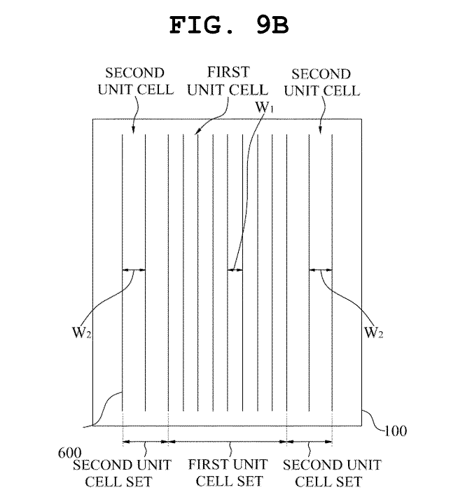

FIGS. 9(A and B) are plan views illustrating a method for manufacturing a thin film type solar cell according to one embodiment of the present invention, which is explained with reference to the aforementioned thin film type solar cell shown in FIG. 3.

As shown in FIG. 9(A), the second unit cell sets are respectively formed at both sides of the substrate 100 simultaneously.

A process for forming the second unit cell sets may use a laser scribing process for forming the separating channel 600 in the predetermined portion of front electrode, semiconductor layer, and rear electrode sequentially deposited on the substrate 100.

The laser scribing process may use a laser apparatus shown in FIG. 12. That is, as shown in FIG. 12, first and second laser sets 900a and 900b including a plurality of lasers are positioned at fixed intervals, and an interval between each of the lasers in the first and second laser sets 900a and 900b is adjusted to the second cell width (W₂). Through the use of laser apparatus including the first and second laser sets 900a and 900b, the second unit cell sets of the second cell width (W₂) are simultaneously formed at both sides of the substrate 100. The number of lasers shown in FIG. 12 may be varied. If needed, an operation for some lasers may be temporarily stopped so as to change the number of lasers, which can be applied to the following embodiments of the present invention.

As shown in FIG. 9(B), the first unit cell set is formed at the central part of the substrate 100.

A process for forming the first unit cell set may use the laser apparatus shown in FIG. 12. In FIG. 12, the interval between each of the lasers is adjusted to the first cell width (W₁) by adjacently positioning the first and second laser sets 900a and 900b including the plurality of lasers. Through the use of laser apparatus, the first unit cell set of the first cell width (W₁) is formed at the central part of the substrate 100.

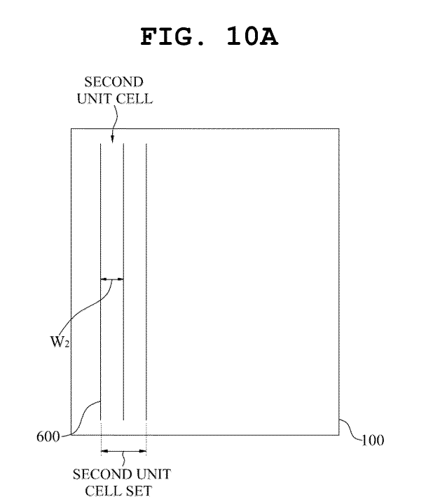

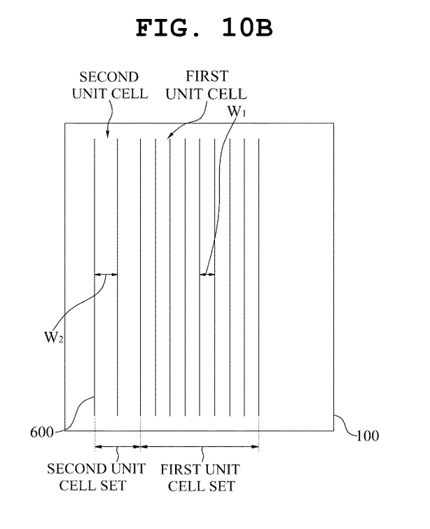

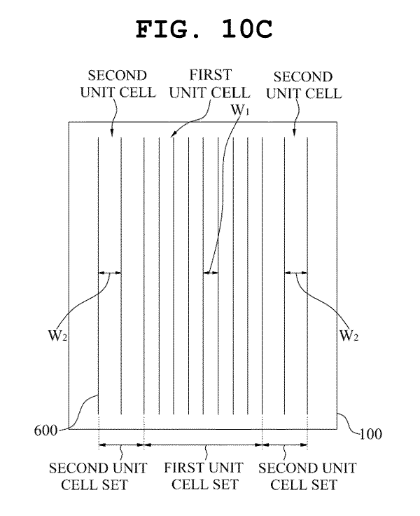

FIGS. 10(A to C) are plan views illustrating another method for manufacturing a thin film type solar cell according to another embodiment of the present invention, which is explained with reference to the aforementioned thin film type solar cell shown in FIG. 3.

As shown in FIG. 10(A), the second unit cell set is formed at one side of the substrate 100.

A process for forming the second unit cell sets may use a laser scribing process for forming the separating channel 600 through the use of laser apparatus shown in FIG. 12. In FIG. 12, the interval between each of the lasers is adjusted to the second cell width (W₂) by adjacently positioning the first and second laser sets 900a and 900b including the plurality of lasers. Through the use of laser apparatus, the second unit cell set of the second cell width (W₂) is formed at one side of the substrate 100.

As shown in FIG. 10(B), the first unit cell set is formed at the central part of the substrate 100.

A process for forming the first unit cell set may use the laser apparatus shown in FIG. 12. In more detail, the interval between each of the lasers of the first and second laser sets 900a and 900b adjacently positioned is adjusted to the first cell width (W₁), and the first unit cell set of the first cell width (W₁) is formed at the central part of the substrate 100 through the use of laser apparatus.

As shown in FIG. 10(C), the second unit cell set is formed at the other side of the substrate 100. This is the same as that of FIG. 10(A), whereby the detailed explanation for this process will be omitted.

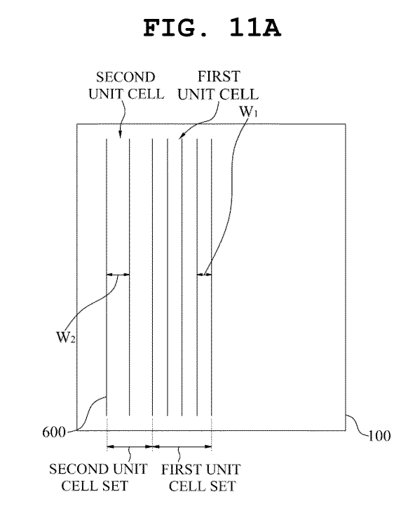

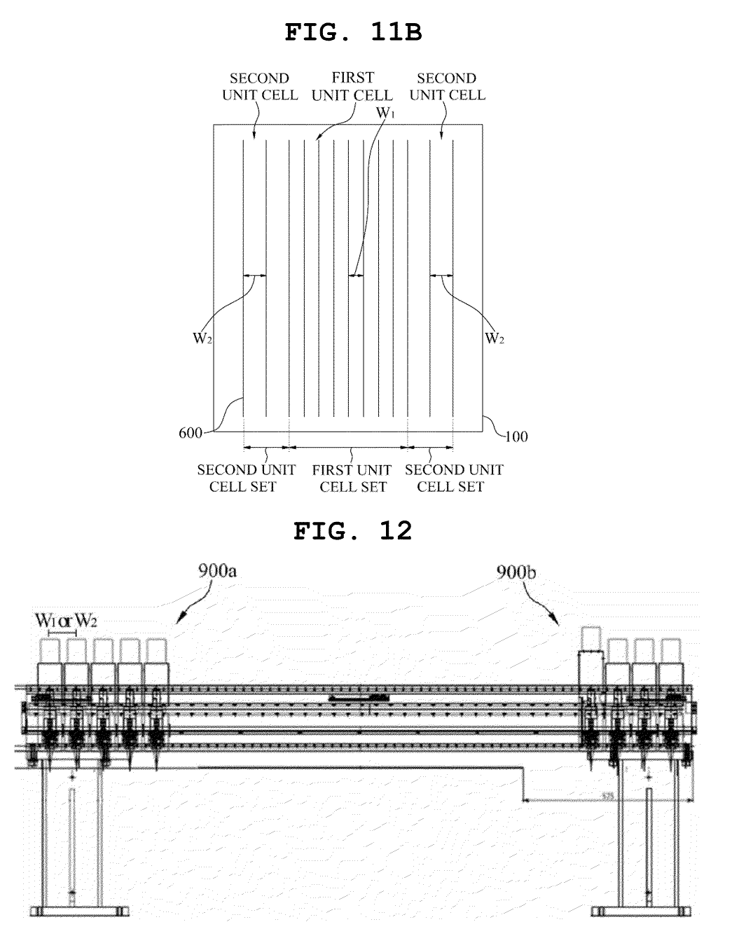

FIGS. 11(A and B) are plan views illustrating another method for manufacturing a thin film type solar cell according to another embodiment of the present invention, which is explained with reference to the aforementioned thin film type solar cell shown in FIG. 3.

As shown in FIG. 11(A), the second unit cell set is formed at one side of the substrate 100, and simultaneously some of the first unit cell set is formed at the central part of the substrate 100.

A process for forming the second unit cell set and some of the first unit cell may use the laser apparatus shown in FIG. 12. After positioning the first and second laser sets 900a and 900b including the plurality of lasers adjacently or at fixed intervals, the interval between each of the lasers of the first laser sets 900a is adjusted to the second cell width (W₂) and the interval between each of the lasers of the second laser sets 900b is adjusted to the first cell width (W₁), and then a laser irradiation is carried out.

As shown in FIG. 11(B), the second unit cell set is formed at the other side of the substrate 100, and simultaneously the remnant of the first unit cell set is formed at the central part of the substrate 100.

A process forming the second unit cell set and the remnant of the first unit cell set may use the laser apparatus shown in FIG. 12. After positioning the first and second laser sets 900a and 900b including the plurality of lasers adjacently or at fixed intervals, the interval between each of the lasers of the first laser sets 900a is adjusted to the first cell width (W₁) and the interval between each of the lasers of the second laser sets 900b is adjusted to the second cell width (W₂), and then a laser irradiation is carried out.

When forming the first and second unit cell sets through the laser scribing process, the first and second unit cell sets may be sequentially formed as shown in FIGS. 9(A and B) and FIGS. 10(A to C), or may be simultaneously formed as shown FIGS. 11(A and B).

As mentioned above, the first unit cell sets occupy about 80 to 95% of an entire area of the unit cells, and the second unit cell sets occupy about 5 to 20% of the entire area of the unit cells.

The aforementioned method for manufacturing the thin film type solar cell is explained with reference to the thin film type solar cell shown in FIG. 3. However, the thin film type solar cells shown in FIGS. 7 and 8 can be manufactured by slightly changing the aforementioned method explained with reference to the thin film type solar cell shown in FIG. 3.

The unit cells in the thin film type solar cell according to the present invention is designed in such a way that the cell width in the unit cell with the relatively-low energy conversion efficiency is larger than the cell width in the unit cell with the relatively-high energy conversion efficiency. Thus, the short-circuit current is increased in the unit cell with the relatively-low energy conversion efficiency, thereby resulting in the improved energy conversion efficiency by improving uniformity of the energy conversion efficiency.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

1. A thin film type solar cell comprising a plurality of unit cells, each unit cell including a front electrode, a semiconductor layer, and a rear electrode sequentially deposited on a substrate,
wherein the thin film type solar cell includes a first unit cell set including at least one first unit cell with a first cell width, and a second unit cell set including at least one second unit cell with a second cell width which is different from the first cell width,
wherein the first unit cell set occupies 80 to 95% of an entire area of the unit cells, and the second unit cell set occupies 5 to 20% of the entire area of the unit cells.

2. The thin film type solar cell of claim 1, wherein the first unit cell set is formed at a central part of the substrate, the second unit cell set is formed at each side of the substrate, and the second cell width of each second unit cell is gradually increased as going toward each end of the substrate.

3. The thin film type solar cell of claim 1, wherein the first unit cell set is formed at one side of the substrate, and the second unit cell set is formed at the other side of the substrate.

4. The thin film type solar cell of claim 1, wherein the semiconductor layer includes first and second semiconductor layers with a buffer layer interposed therebetween.

5. A thin film type solar cell comprising first and second solar cells on a substrate, wherein the first and second solar cells are formed at a predetermined interval therebetween so as to be separately driven when cutting the substrate into the first and second solar cells,
wherein each of the first and second solar cells includes a plurality of unit cells, each unit cell including a front electrode, a semiconductor layer, and a rear electrode deposited in sequence, and
wherein the plurality of unit cells constitute a first unit cell set provided with first unit cells and a second unit cell set provided with second unit cells, wherein each of the first unit cells has a first cell width, each of the second unit cells has a second cell width, and the first cell width is different from the second cell width, and
wherein the first unit cell set occupies 80 to 95% of an entire area of the unit cells, and the second unit cell set occupies 5 to 20% of the entire area of the unit cells.

6. The thin film type solar cell of claim 5, wherein the first unit cell set is formed at a central part of the substrate, and the second unit cell set is formed at each side of the substrate.

7. The thin film type solar cell of claim 6, wherein the second cell width of each second unit cell is gradually increased as going toward each end of the substrate.

8. The thin film type solar cell of claim 5, wherein the first and second unit cells sets are arranged in such a way that the second unit cell set is positioned at a central part of the substrate, the first unit cell sets are symmetrically positioned with respect to the centrally-positioned second unit cell set; and the second unit cell set is positioned next to each first unit cell set.

9. The thin film type solar cell of claim 5, wherein the second unit cells are symmetrically positioned with respect to the first unit cell set positioned at the central part of the substrate in each of the first and second solar cells.

10. The thin film type solar cell of claim 5, wherein the same type unit cell sets are formed at the neighboring sides of the first and second solar cells.

11. A thin film type solar cell module comprising:
a thin film type solar cell including a plurality of unit cells, each unit cell including a front electrode, a semiconductor layer, and a rear electrode sequentially deposited on a substrate, wherein the plurality of unit cells constitute a first unit cell set including at least one first unit cell with a first cell width, and a second unit cell set including at least one second unit cell with a second cell width which is different from the first cell width, and wherein the first unit cell set occupies 80 to 95% of an entire area of the unit cells, and the second unit cell set occupies 5 to 20% of the entire area of the unit cells;
a first connection wire for connecting the front electrode of the unit cell formed at one side of the substrate with the external, and a second connection wire for connecting the rear electrode of the unit cell formed at the other side of the substrate with the external; and
a support frame for supporting the thin film type solar cell.

12. A power generation system comprising a thin film type solar cell module and a power inverting device for inverting an output of the thin film type solar cell module,
wherein the thin film type solar cell module comprises:
a thin film type solar cell including a plurality of unit cells, each unit cell including a front electrode, a semiconductor layer, and a rear electrode sequentially deposited on a substrate, wherein the plurality of unit cells constitute a first unit cell set including at least one first unit cell with a first cell width, and a second unit cell set including at least one second unit cell with a second cell width which is different from the first cell width, and wherein the first unit cell set occupies 80 to 95% of an entire area of the unit cells, and the second unit cell set occupies 5 to 20% of the entire area of the unit cells;
a first connection wire for connecting the front electrode of the unit cell formed at one side of the substrate with the external, and a second connection wire for connecting the rear electrode of the unit cell formed at the other side of the substrate with the external; and
a support frame for supporting the thin film type solar cell.

13. A method for manufacturing a thin film type solar cell including a plurality of unit cells, each unit cell including a front electrode, a semiconductor layer, and a rear electrode sequentially deposited on a substrate, comprising:
forming a first unit cell set including at least one first unit cell with a first cell width; and
forming a second unit cell set including at least one second unit cell with a second cell width, wherein the second cell width is different from the first cell width,
wherein the first and second unit cell sets are formed by a laser scribing process using at least one laser for forming a separating channel.

14. The method of claim 13, wherein the laser scribing process comprises:
forming any one of the first and second unit cell sets; and
forming the other of the first and second unit cell sets.

15. The method of claim 14, wherein the laser scribing process comprises:
forming the second unit cell set at one side of the substrate after adjusting an interval between each of the lasers to the second cell width;
forming the first unit cell set at a central part of the substrate after adjusting an interval between each of the lasers to the first cell width; and
forming the second unit cell set at the other side of the substrate after an interval between each of the lasers to the second cell width.

16. The method of claim 14, wherein the laser scribing process comprises:
forming the second unit cell sets at both sides of the substrate at the same time after adjusting an interval between each of the lasers to the second cell width; and
forming the first unit cell set at the central part of the substrate after adjusting an interval between each of the lasers to the first cell width.

17. The method of claim 13, wherein steps of forming the first and second unit cell sets by the laser scribing process are started at the same time.

18. The method of claim 17, wherein the laser scribing process comprises:
forming the second unit cell set at one side of the substrate and simultaneously forming some of the first unit cell set at a central part of the substrate after adjusting an interval between each of some lasers to the second cell width and an interval between each of the remnant lasers to the first cell width; and
forming the remnant of the first unit cell at the central part of the substrate and simultaneously forming the second unit cell set at the other side of the substrate after adjusting an interval between each of some lasers to the first cell width and an interval between each of the remnant lasers to the second cell width.

19. The method of claim 13, wherein the first unit cell set occupies 80 to 95% of an entire area of the unit cells, and the second unit cell set occupies 5 to 20% of the entire area of the unit cells.
